(19) United States
(12) Patent Application Publication
(10) Pub. No.: US 2011/0211406 A1
(43) Pub. Date: Sep. 1, 2011

(54) ADDRESS DELAY CIRCUIT

(75) Inventors: Jae Bum KO, Ichon-shi (KR); Jong Chern Lee, Ichon-shi (KR)

(73) Assignee: Hynix Semiconductor Inc., Ichon-shi (KR)

(21) Appl. No.: 12/840,199

(22) Filed: Jul. 20, 2010

(30) Foreign Application Priority Data
Feb. 26, 2010 (KR) 10-2010-0017780

(51) Int. Cl. G11C 7/00

(52) U.S. Cl. 365/194; 365/233.1

(57) ABSTRACT

An address delay circuit of a semiconductor memory apparatus includes a control clock delay block configured to receive a clock as a first control clock in response to a first input control signal, and output external address as the first delayed address; a control clock input selecting delay block configured to receive the clock as a second control clock in response to a second input control signal, select whether to receive the external address or the first delayed address in response to the first input control signal, and output the selected address as the second delayed address; and a control clock input/output selecting delay block configured to receive the clock, select whether to receive the external address or the second delayed address in response to the second input control signal, and output the selected address as an internal address.

### CROSS-REFERENCES TO RELATED APPLICATION

The present application claims priority under 35 U.S.C. §119(a) to Korean Application No. 10-2010-0017780, filed on Feb. 26, 2010, in the Korean Intellectual Property Office, which is incorporated herein by reference in its entirety as if set forth in full.

### BACKGROUND

1. Technical Field

The present invention relates to a semiconductor integrated circuit, and more particularly, to an address delay circuit.

2. Related Art

A semiconductor memory apparatus operates in synchronization with a clock, and internal circuits of the semiconductor memory apparatus are also designed to operate in synchronization with the clock.

All external signals inputted from outside of the semiconductor memory apparatus are synchronized with the clock in the semiconductor memory apparatus which are to be used as internal signals.

External addresses inputted to the semiconductor memory apparatus are also synchronized with the clock and are converted as internal addresses. The internal addresses thus converted are used after being delayed according to the operation mode of the semiconductor memory apparatus, e.g., a read operation or a write operation.

FIG. 1 is a block diagram illustrating a typical address delay circuit of a semiconductor memory apparatus. Referring to FIG. 1, the typical address delay circuit includes a delay unit 10, an input selecting delay unit 20, and an input/output selecting delay unit 30.

The delay unit 10 comprises a plurality of flip-flops coupled in series (not shown) for receiving and outputting an input signal in response to a clock CLK. Accordingly, after cycles of the clock CLK corresponding to the number of the flip-flops coupled in series in the delay unit 10, an external address add<0:3> is outputted as a first delayed address add_d1<0:3>.

Although the input selecting delay unit 20 has a similar configuration as the delay unit 10, the input selecting delay unit 20 is configured to selectively receive the first delayed address add_d1<0:3> or the external address add<0:3> in response to a first input control signal ctrl_in1. The input selecting delay unit 20 selects the first delayed address add_d1<0:3> or the external address add<0:3> in response to the first input control signal ctrl_in1, and outputs the selected address as a second delayed address add_d2<0:3> after cycles of the clock CLK corresponding to the number of the flip-flops (not shown) in the input selecting delay unit 20.

The input/output selecting delay unit 30 is configured to selectively receive the second delayed address add_d2<0:3> or the external address add<0:3> in response to a second input control signal ctrl_in2, and determine the number of flip-flops (not shown) through which the received address is to be outputted as internal an address add_int<0:3> in response to output control signals ctrl_out<0:2>.

The typical address delay circuit of a semiconductor memory apparatus, configured as mentioned above, operates as described below.

The delay unit 10 delays the external address add<0:3> corresponding to the number of the flip-flops in the delay unit 10, and generates the first delayed address add_d1<0:3>.

The input selecting delay unit 20 selectively receives the external address add<0:3> or the first delayed address add_d1<0:3> in response to the first input control signal ctrl_in1. Also, the input selecting delay unit 20 delays the selectively received address corresponding to the number of the flip-flops therein and generates the second delayed address add_d2<0:3>.

The input/output selecting delay unit 30 selectively receives the second delayed address add_d2<0:3> or the external address add<0:3> in response to the second input control signal ctrl_in2. Also, the input/output selecting delay unit 30 determines the number of flip-flops through which the received address is to be delayed in response to the output control signals ctrl_out<0:2>, and outputs the delayed address as an internal address add_int<0:3>.

Referring to FIG. 2, the input/output selecting delay unit 30 includes an input/output selecting flip-flop 31, and first and second output selecting flip-flops 32 and 33.

The input/output selecting flip-flop 31 selects the second delayed address add_d2<0:3> or the external address add<0:3> in response to the second input control signal ctrl_in2, and receives and stores the selected address according to the clock CLK. The input/output selecting flip-flop 31 selects whether to output the stored address to the first output selecting flip-flop 32 or as the internal address add_int<0:3> in response to the output control signal ctrl_out<0>, and outputs the stored address through a selected path according to the clock CLK.

The first output selecting flip-flop 32 selects whether to output the output of the input/output selecting flip-flop 31 to the second output selecting flip-flop 33 or as the internal address add_int<0:3> in response to the output control signal ctrl_out<1>, and outputs the output of the input/output selecting flip-flop 31 through the selected path according to the clock CLK.

The second output selecting flip-flop 33 selects whether to output the output of the first output selecting flip-flop 32 through a first output terminal out1 or through a second output terminal out2 as the internal address add_int<0:3> in response to the output control signal ctrl_out<2>, and outputs the output of the first output selecting flip-flop 32 through the selected path according to the clock CLK.

If the input/output selecting delay unit 30 selects the external address add<0:3> between the external address add<0:3> and the second delayed address add_d2<0:3>, the second delayed address add_d2<0:3> generated through the delay unit 10 and the input selecting delay unit 20 is not necessary since it is not used in the input/output selecting delay unit 30, thereby increasing power consumption.

Also, if the input selecting delay unit 20 selects the external address add<0:3> between the external address add<0:3> and the first delayed address add_d1<0:3>, the first delayed address add_d1<0:3> generated by the delay unit 10 is not necessary since it is not used in the input selecting delay unit 20, thereby increasing power consumption.

In particular, in the delay unit 10, the input selecting delay unit 20 and the input/output selecting delay unit 30 which delay the address using the flip-flops, since the flip-flops disposed therein operate in synchronization with the clock, the unnecessary power consumption further increases as the clock frequency increases.

In the input/output selecting delay unit 30, if the output of the input/output selecting flip-flop 31 is outputted as the internal address add_int<0:3>, unnecessary power consumption is caused since the first and second output selecting flip-flops 32 and 33 unnecessarily operate according to the clock CLK.

Moreover, in the input/output selecting delay unit 30, if the address delayed through the input/output selecting flip-flop 31 and the first output selecting flip-flop 32 are outputted as the internal address add_int<0:3>, unnecessary power consumption is caused since the second output selecting flip-flop 33 unnecessarily operates according to the clock CLK.

### SUMMARY

Accordingly, various exemplary embodiments of the invention may provide an address delay circuit of a semiconductor memory apparatus which can reduce power consumption compared to a typical address delay circuit.

In one embodiment of the present invention, an address delay circuit includes: a control clock delay block configured to receive a clock as a first control clock in response to a first input control signal, and output external address as first delayed address after a predetermined number of cycles of the first control clock; a control clock input selecting delay block configured to receive the clock as a second control clock in response to a second input control signal, select whether to receive the external address or the first delayed address in response to the first input control signal, and output the selected address as second delayed address after a predetermined number of cycles of the second control clock; and a control clock input/output selecting delay block configured to receive the clock, select whether to receive the external address or the second delayed address in response to the second input control signal, and output the selected address as internal address after a predetermined number of cycles of the clock elapse, wherein the predetermined number of cycles of the clock is determined by output control signals.

In another embodiment of the present invention, an address delay circuit includes: a delay unit including a plurality of flip-flops coupled in series, and configured to output an external address as delayed address after delaying the external address; a control clock input/output selecting delay unit configured to selectively receive the external address or the delayed address in response to an input control signal, and output the received address as an internal address after delaying the received address; and a clock control unit configured to provide a clock or a signal fixed to a specific level, to the flip-flops in response to the input control signal.

In another embodiment of the present invention, an address delay circuit includes: a delay unit configured to output external address as a delayed address after delaying the external address; a first output selecting flip-flop configured to delay the delayed address, and output the delayed address through a first output terminal or a second output terminal in response to an output control signal; a second output selecting flip-flop configured to delay a signal outputted from the first output terminal of the first output selecting flip-flop, and output the signal outputted from the first output terminal of the first output selecting flip-flop as an internal address; and a clock control unit configured to provide a clock to the second output selecting flip-flop as a control clock in response to the output control signal.

### BRIEF DESCRIPTION OF THE DRAWINGS

Features, aspects, and embodiments are described in conjunction with the attached drawings, in which:

FIG. 1 is a block diagram illustrating a typical address delay circuit of a semiconductor memory apparatus;

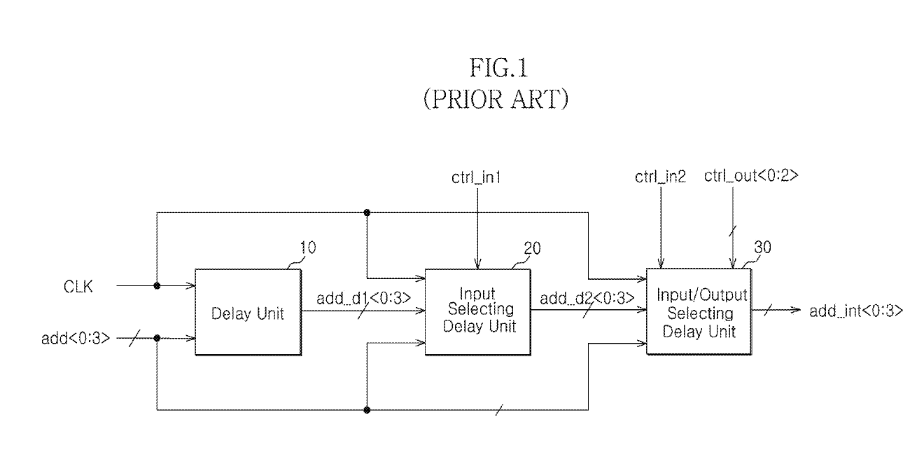

FIG. 2 is a diagram illustrating a configuration of the input/output selecting delay unit shown in FIG. 1;

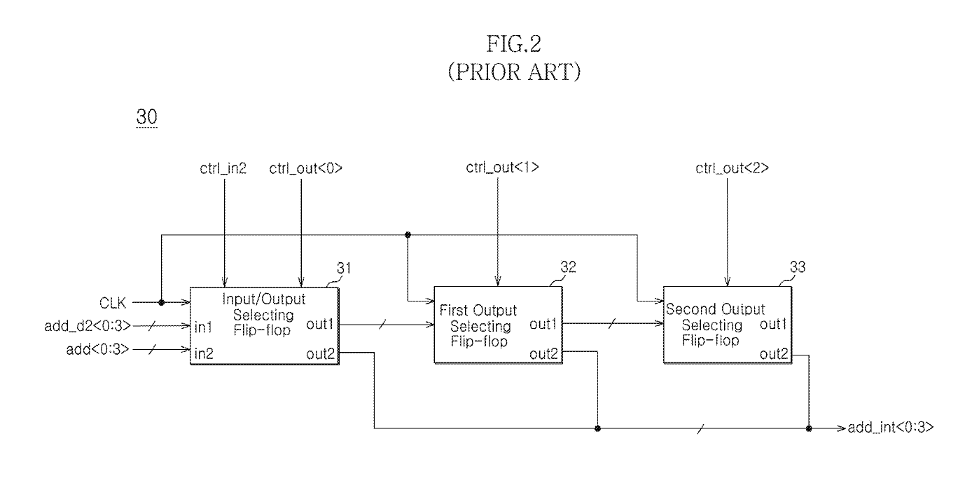

FIG. 3 is a block diagram schematically illustrating an address delay circuit of a semiconductor memory apparatus in accordance with an embodiment of the present invention;

FIG. 4 is a diagram illustrating a configuration of the delay unit shown in FIG. 3;

FIG. 5 is a diagram illustrating a configuration of the input selecting delay unit shown in FIG. 3;

FIG. 6 is a diagram illustrating a configuration of the control clock input/output selecting delay block shown in FIG. 3; and

FIG. 7 is a diagram illustrating a configuration of the first through fourth clock control units shown in FIGS. 3 and 6.

### DETAILED DESCRIPTION

Reference will now be made in detail to the exemplary embodiments consistent with the present disclosure, examples of which are illustrated in the accompanying drawings. Whenever possible, the same reference numerals will be used throughout the drawings to refer to the same or like parts.

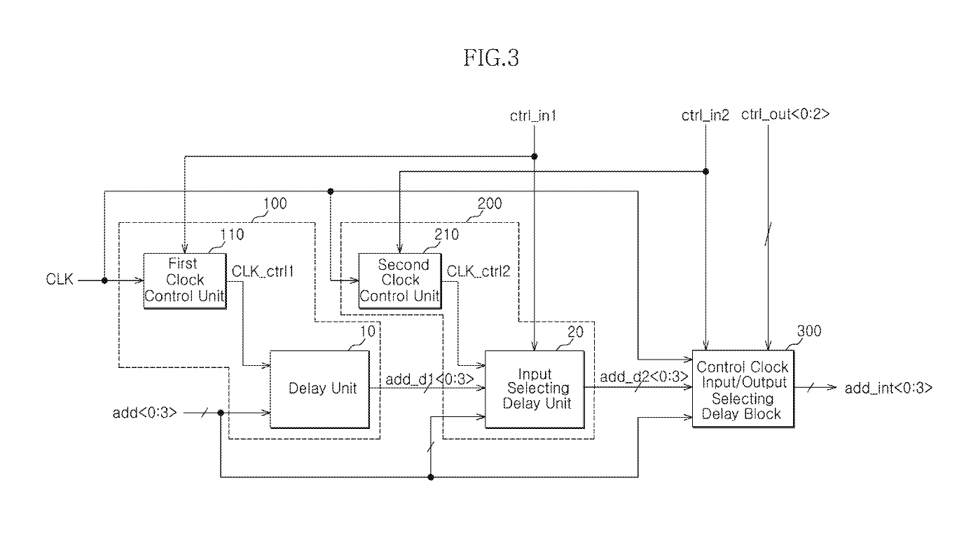

Referring to FIG. 3, an address delay circuit of a semiconductor memory apparatus in accordance with an embodiment of the present invention may include a control clock delay block 100, a control clock input selecting delay block 200, and a control clock input/output selecting delay block 300.

The control clock delay block 100 is configured to receive a clock CLK as a first control clock CLK_ctrl1 in response to a first input control signal ctrl_in1, and output an external address add<0:3> as a first delayed address add_d1<0:3> after a predetermined number of cycles of the first control clock CLK_ctrl1.

The control clock delay block 100 may include a first clock control unit 110 and a delay unit 10.

The first clock control unit 110 is configured to output the clock CLK as the first control clock CLK_ctrl1 when the first input control signal ctrl_in1 is enabled, and hold the first control clock CLK_ctrl1 to a specific level when the first input control signal ctrl_in1 is disabled.

The delay unit 10 is configured to output the external address add<0:3> as the first delayed address add_d1<0:3> after the predetermined number of cycles of the first control clock CLK_ctrl1.

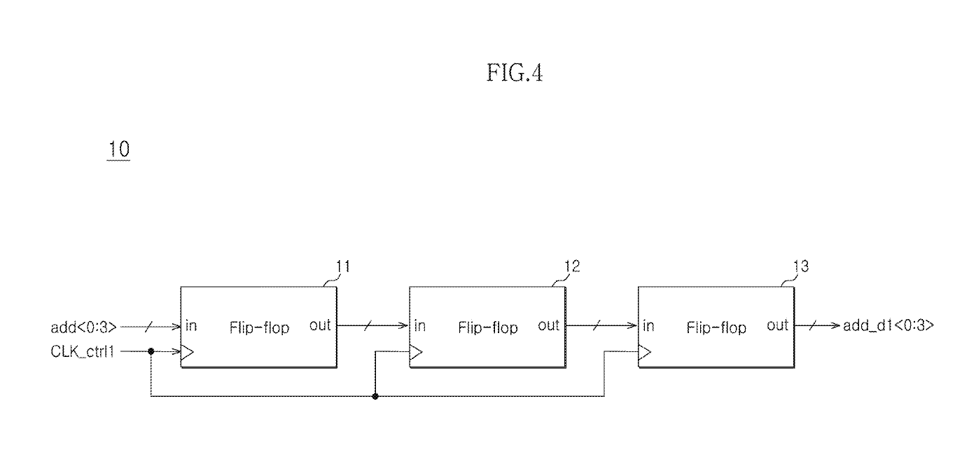

For example, assuming that the delay unit 10 outputs the external address add<0:3> as the first delayed address add_d1<0:3> after three cycles of the first control clock CLK_ctrl1, the delay unit 10 includes three flip-flops 11, 12 and 13 which are coupled in series as shown in FIG. 4. Referring to FIG. 4, each of the flip-flops 11, 12 and 13 outputs the signal inputted thereto as an output signal after one cycle of the first control clock CLK_ctrl1.

The control clock input selecting delay block 200 is configured to receive the clock CLK as a second control clock CLK_ctrl2 in response to a second input control signal ctrl_in2, select whether to receive the external address add<0:3> or the first delayed address add_d1<0:3> in response to the first input control signal ctrl_in1, and output the selected address as a second delayed address add_d2<0:3> after a predetermined number of cycles of the second control clock CLK_ctrl2.

The control clock input selecting delay block 200 may include a second clock control unit 210 and an input selecting delay unit 20.

The second clock control unit 210 is configured to output the clock CLK as the second control clock CLK_ctrl2 when the second input control signal ctrl_in2 is enabled, and hold the second control clock CLK_ctrl2 to a specific level when the second input control signal ctrl_in2 is disabled.

The input selecting delay unit 20 is configured to select whether to receive the external address add<0:3> or the first delayed address add_d1<0:3> in response to the first input control signal ctrl_in1, and output the selected address (one of the external address add<0:3> and the first delayed address add_d1<0:3>) as the second delayed address add_d2<0:3> after the predetermined number of cycles of the second control clock CLK_ctrl2.

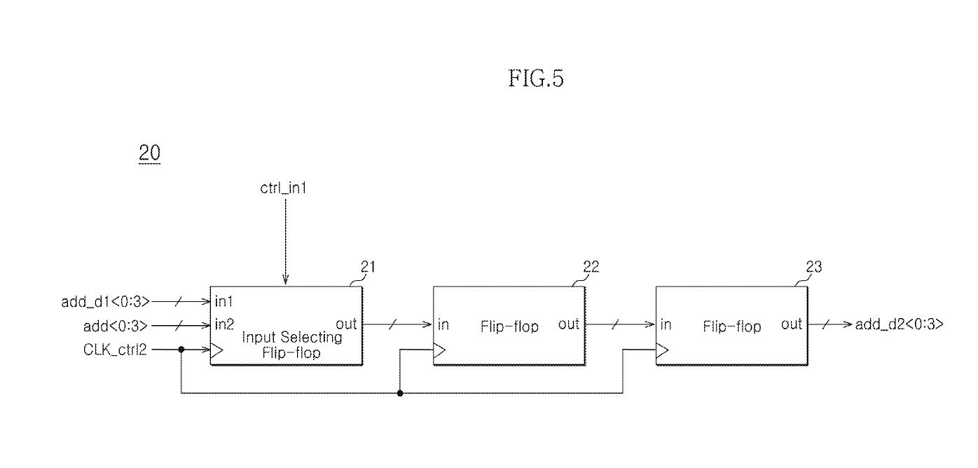

For example, assuming that the input selecting delay unit 20 outputs the selected address (one of the external address add<0:3> and the first delayed address add_d1<0:3>) as the second delayed address add_d2<0:3> after three cycles of the second control clock CLK_ctrl2, the input selecting delay unit 20 may include three flip-flops 21, 22 and 23 which are coupled in series as shown in FIG. 5. Referring to FIG. 5, the first flip-flop 21 of the input selecting delay unit 20 selectively receives the first delayed address add_d1<0:3> or the external address add<0:3> in response to the first input control signal ctrl_in1. Each of the flip-flops 21, 22 and 23 of the input selecting delay unit 20 outputs the signal inputted thereto as an output signal after one cycle of the second control clock CLK_ctrl2.

The control clock input/output selecting delay block 300 is configured to receive the clock CLK, select whether to receive the external address add<0:3> or the second delayed address add_d2<0:3> in response to the second input control signal ctrl_in2, and output the selected address as the internal address add_int<0:3> after a predetermined number of cycles of the clock CLK. The number of cycles of the clock CLK is determined by output control signals ctrl_out<0:2>.

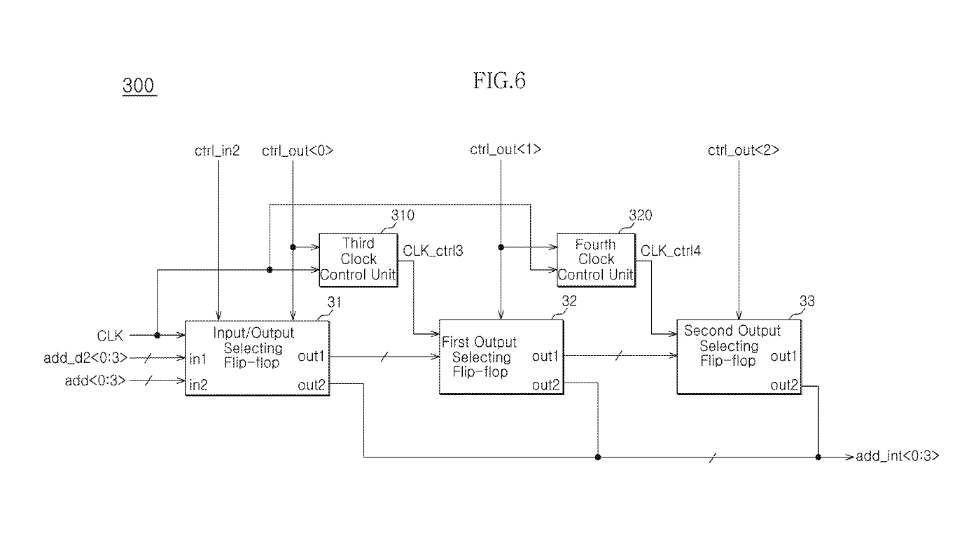

Referring to FIG. 6, the control clock input/output selecting delay block 300 may include an input/output selecting flip-flop 31, a first output selecting flip-flop 32, a second output selecting flip-flop 33, a third clock control unit 310, and a fourth clock control unit 320.

The input/output selecting flip-flop 31 selects whether to receive the external address add<0:3> or the second delayed address add_d2<0:3> in response to the second input control signal ctrl_in2, selects whether to output the selected address (one of the external address add<0:3> and the second delayed address add_d2<0:3>) through a first output terminal out1 or a second output terminal out2 in response to the output control signal ctrl-out<0> after one cycle of the clock CLK, and output the selected address through the selected path.

The third clock control unit 310 is configured to output the clock CLK as a third control clock CLK_ctrl3 in response to the output control signal ctrl_out<0>. For example, the third clock control unit 310 outputs the clock CLK as the third control clock CLK_ctrl3 when the output control signal ctrl_out<0> is enabled, and holds the third control clock CLK_ctrl3 to a specific level when the output control signal ctrl_out<0> is disabled.

The first output selecting flip-flop 32 outputs the signal received from a first output terminal out1 of the input/output selecting flip-flop 31 after one cycle of the third control clock CLK_ctrl3 elapses. The first output selecting flip-flop 32 outputs the output signal of the input/output selecting flip-flop 31 through the first output terminal out1 or the second output terminal out2 in response to the output control signal ctrl_out<1>.

The fourth clock control unit 320 is configured to output the clock CLK as a fourth control clock CLK_ctrl4 in response to the output control signal ctrl_out<1>. For example, the fourth clock control unit 320 outputs the clock CLK as the fourth control clock CLK_ctrl4 when the output control signal ctrl_out<1> is enabled, and holds the fourth control clock CLK_ctrl4 to a specific level when the output control signal ctrl_out<1> is disabled.

The second output selecting flip-flop 33 outputs the signal received from the first output terminal out1 of the first output selecting flip-flop 32 after one cycle of the fourth control clock CLK_ctrl4 elapses. The second output selecting flip-flop 33 outputs the output signal of the first output selecting flip-flop 32 through the first output terminal out1 or the second output terminal out2 in response to the output control signal ctrl_out<2>. The second output terminal out2 of the input/output selecting flip-flop 31, the first output selecting flip-flop 32 and the second output selecting flip-flop 33 are commonly coupled with one another, and the internal address add_int<0:3> are outputted from a node to which they are commonly coupled.

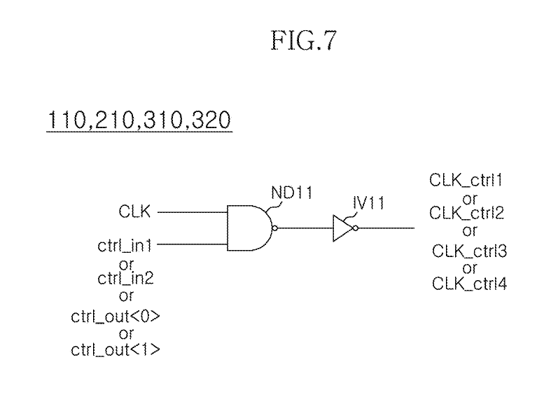

Referring to FIG. 7, each of the first to fourth clock control units 110, 210, 310 and 320 may include a NAND gate ND11 and an inverter IV11. The NAND gate ND11 receives the clock CLK through its first input terminal, and receives one of the first and second input control signals ctrl_in1 and ctrl_in2 or one of the output control signals ctrl_out<0> and ctrl_out<1> through its second input terminal depending upon which clock control unit 110, 210, 310 or 320 the NAND gate ND11 is included in. The inverter IV11 receives the output signal of the NAND gate ND11, and outputs one of the first to fourth control clocks CLK_ctrl1-CLK_ctrl4 depending upon which clock control unit 110, 210, 310 or 320 the inverter IV11 is included.

The address delay circuit of a semiconductor memory apparatus in accordance with the embodiment of the present invention, configured as mentioned above, operates as described below.

It is assumed that the delay unit 10 and the input selecting delay unit 20 shown in FIG. 3 output the signal inputted thereto after three cycles of the clock CLK.

The address delay circuit of a semiconductor memory apparatus in accordance with the embodiment of the present invention may receive the external address add<0:3> and output the external address add<0:3> as the internal address add_int<0:3> after nine cycles of the clock CLK as a maximum delay.

When the first input control signal ctrl_in1 is enabled, the first clock control unit 110 outputs the clock CLK as the first control clock CLK_ctrl1. If the first control clock CLK_ctrl1 is inputted to the delay unit 10, the delay unit 10 outputs the external address add<0:3> as the first delayed address add_d1<0:3> after three cycles of the clock CLK.

When the first input control signal ctrl_in1 is enabled, the input selecting delay unit 20 receives the first delayed address add_d1<0:3> between the first delayed address add_d1<0:3> and the external address add<0:3>. If the first input control signal ctrl_in1 is disabled, the input selecting delay unit 20 receives the external address add<0:3> between the first delayed address add_d1<0:3> and the external address add<0:3>.

If the first input control signal ctrl_in1 is disabled, the delay unit 10 receives the first control clock CLK_ctrl1 held to the specific level, thus does not operate.

When the second input control signal ctrl_in2 is enabled, the second clock control unit 210 outputs the clock CLK as the second control clock CLK_ctrl2. If the second control clock CLK_ctrl2 is inputted to the input selecting delay unit 20, the input selecting delay unit 20 outputs the address selected by the first input control signal ctrl_in1 (add_d1<0:3> or add<0:3>) as the second delayed address add_d2<0:3> after three cycles of the clock CLK.

If the second input control signal ctrl_in2 is enabled, the control clock input/output selecting delay block 300 receives the second delayed address add_d2<0:3>. If the second input control signal ctrl_in2 is disabled, the control clock input/output selecting delay block 300 receives the external address add<0:3>.

The control clock input/output selecting delay block 300 outputs the address inputted in response to the second input control signal ctrl_in2 (add_d2<0:3> or add<0:3>) as the internal address add<0:3> after one, two or three cycles of the clock CLK according to the output control signals ctrl_out<0:2>. The control clock input/output selecting delay block 300 will be described in detail with reference to FIG. 6.

Referring to FIG. 6, if all the output control signals ctrl_out<0:2> are disabled, the third and fourth clock control units 310 and 320 output the third and fourth control clocks CLK_ctrl3 and CLK_ctrl4 which are held to the specific level. The input/output selecting flip-flop 31 outputs the address inputted in response to the second input control signal ctrl_in2 (add_d2<0:3> or add<0:3>) through the second output terminal out2 after one cycle of the clock CLK. The signal from the input/output selecting flip-flop 31 is outputted as the internal address add_int<0:3>. Meanwhile, the first and second output selecting flip-flops 32 and 33 do not operate since they receive the third and fourth control clocks CLK_ctrl3 and CLK_ctrl4 which are held to the specific level.

If only ctrl_out<0> is enabled among the output control signals ctrl_out<0:2>, the input/output selecting flip-flop 31 outputs its output signal to the first output selecting flip-flop 32 through the first output terminal out1. The third clock control unit 310 inputs the clock CLK to the first output selecting flip-flop 32 as the third control clock CLK_ctrl3. Accordingly, the address inputted in response to the second input control signal ctrl_in2 are outputted as the internal address add_int<0:3> through the input/output selecting flip-flop 31 and the first output selecting flip-flop 32, and are outputted from the second output terminal out2 of the first output selecting flip-flop 32 after two cycles of the clock CLK.

If only ctrl_out<0> and ctrl<1> are enabled among the output control signals ctrl_out<0:2>, the third and fourth clock control units 310 and 320 output the clock CLK as the third and fourth control clocks CLK_ctrl3 and CLK_ctrl4, respectively. The address selected by the second input control signal ctrl_in2 is transferred to the second output selecting flip-flop 33 through the input/output selecting flip-flop 31 and the first output selecting flip-flop 32, which receive the third and fourth control clocks CLK_ctrl3 and CLK_ctrl4. Since the internal address add_int<0:3> outputted from the second output selecting flip-flop 33 are transferred through the input/output selecting flip-flop 31 and the first and second output selecting flip-flops 32 and 33, the address inputted in response to the second input control signal ctrl_in2 is outputted as the internal address add_int<0:3> after three cycles of the clock CLK.

As a result, according to the first and second input control signals ctrl_in1 and ctrl_in2, the external address add<0:3> is inputted directly to the control clock input/output selecting delay block 300, or are inputted to the control clock input/output selecting delay block 300 after a delay of three or six cycles of the clock CLK. The control clock input/output selecting delay block 300 outputs the inputted address as the internal address add_int<0:3> after one, two or three cycles of the clock CLK according to the output control signals ctrl_out<0:2>.

When outputting the external address as the internal address after a minimum number of cycles (one cycle), the address delay circuit of a semiconductor memory apparatus in accordance with the embodiment of the present invention prevents the delay unit 10, the input selecting delay unit 20, and the first and second output selecting flip-flops 32 and 33 from receiving a toggling clock, thereby reducing power consumption compared to the conventional art. When the number of cycles of the clock as a delay period increases or decreases by the unit of three, the toggling clock is selectively inputted to the delay unit 10 or the input selecting delay unit 20, and when the predetermined number of cycles of the clock increases or decreases by the unit of one, the toggling clock is selectively inputted to the input/output selecting flip-flop 31 and the first and second output selecting flip-flops 32 and 33 of the control clock input/output selecting delay block 300, thereby reducing power consumption compared to the conventional art.

While a certain embodiment has been described above with reference to illustrative examples for particular applications, it will be understood to those skilled in the art that the embodiment described is by way of example only. Those skilled in the art with access to the teachings provided in this disclosure will recognize additional modifications, applications, and/or embodiments and additional fields in which the present disclosure would be of significant utility. Accordingly, the address delay circuit described herein should not be limited based on the described embodiment. Rather, the address delay circuit described herein should only be limited in light of the claims that follow when taken in conjunction with the above description and accompanying drawings.

What is claimed is:

1. An address delay circuit comprising:
a control clock delay block configured to receive a clock as a first control clock in response to a first input control signal, and output an external address as a first delayed address after a predetermined number of cycles of the first control clock;
a control clock input selecting delay block configured to receive the clock as a second control clock in response to a second input control signal, select whether to receive the external address or the first delayed address in response to the first input control signal, and output the selected address as a second delayed address after a predetermined number of cycles of the second control clock; and
a control clock input/output selecting delay block configured to receive the clock, select whether to receive the external address or the second delayed address in response to the second input control signal, and output the selected address as an internal address after a predetermined number of cycles of the clock elapse,
wherein the predetermined number of cycles of the clock is determined by output control signals.

2. The address delay circuit according to claim 1, wherein the control clock delay block comprises:
a clock control unit configured to output the clock as the first control clock when the first input control signal is enabled, and hold the first control clock to a specific level when the first input control signal is disabled; and
a delay unit configured to output the external address as the first delayed address after the predetermined number of cycles of the first control clock.

3. The address delay circuit according to claim 2, wherein the delay unit comprises a plurality of flip-flops coupled in series to receive and store input signals in response to the first control clock and output the stored signals.

4. The address delay circuit according to claim 3, wherein the predetermined number of cycles of the first control clock corresponds to the number of the flip-flops.

5. The address delay circuit according to claim 1, wherein the control clock input selecting delay block comprises:
a clock control unit configured to output the clock as the second control clock when the second input control signal is enabled, and hold the second control clock to a specific level when the second input control signal is disabled; and
an input selecting delay unit configured to select whether to receive the external address or the first delayed address in response to the first input control signal, and output the selected address as the second delayed address after the predetermined number of cycles of the second control clock.

6. The address delay circuit according to claim 5, wherein the input selecting delay unit comprises a plurality of flip-flops coupled in series to receive and store input signals in response to the second control clock and output the stored signals.

7. The address delay circuit according to claim 6, wherein the predetermined number of cycles of the second control clock corresponds to the number of the flip-flops.

8. The address delay circuit according to claim 1,
wherein the output control signals comprise a first output control signal, a second output control signal, and a third output control signal,
wherein the control clock input/output selecting delay block comprises:
an input/output selecting flip-flop configured to select whether to receive the external address or the second delayed address in response to the second input control signal, select whether to output the selected address through a first output terminal or a second output terminal in response to the first output control signal, and output the selected address through the selected output terminal after one cycle of the clock;
a first clock control unit configured to output the clock as a third control clock in response to the first output control signal;
a first output selecting flip-flop configured to select whether to output a signal outputted from the first output terminal of the input/output selecting flip-flop through a first output terminal or a second output terminal in response to the second output control signal, and output the signal outputted from the first output terminal of the input/output selecting flip-flop through the selected output terminal after one cycle of the third control clock;
a second clock control unit configured to output the clock as a fourth control clock in response to the second output control signal; and
a second output selecting flip-flop configured to select whether to output a signal outputted from the first output terminal of the first output selecting flip-flop through a first output terminal or a second output terminal in response to the third output control signal, and output the signal outputted from the first output terminal of the first output selecting flip-flop through the selected output terminal after one cycle of the fourth control clock, and
wherein the internal address is outputted from a node to which the second output terminal of the input/output selecting flip-flop, the second output terminal of the first output selecting flip-flop, and the second output terminal of the second output selecting flip-flop are commonly coupled.

9. An address delay circuit comprising:
a delay unit including a plurality of flip-flops coupled in series, and configured to output external address as delayed address after delaying the external address;
a control clock input/output selecting delay unit configured to selectively receive the external address or the delayed address in response to an input control signal, and output the received address as internal address after delaying the received address; and
a clock control unit configured to provide a clock or a signal held to a specific level, to the flip-flops in response to the input control signal.

10. The address delay circuit according to claim 9, wherein the clock control unit provides the clock to the flip-flops when the input control signal is enabled, and provides the signal held to the specific level to the flip-flops when the input control signal is disabled.

11. The address delay circuit according to claim 10, wherein the control clock input/output selecting delay unit receives and delays the delayed address and outputs the delayed address as the internal address when the input control signal is enabled, and receives and delays the external address and outputs the external address as the internal address when the input control signal is disabled.

12. An address delay circuit comprising:
a delay unit configured to output external address as delayed address after delaying the external address;
a first output selecting flip-flop configured to delay the delayed address, and output the delayed address through a first output terminal or a second output terminal in response to an output control signal;
a second output selecting flip-flop configured to delay a signal outputted from the first output terminal of the first output selecting flip-flop, and output the signal outputted from the first output terminal of the first output selecting flip-flop as an internal address; and
a clock control unit configured to provide a clock to the second output selecting flip-flop as a control clock in response to the output control signal.

13. The address delay circuit according to claim 12, wherein the clock control unit provides the clock to the second output selecting flip-flop as the control clock when the output control signal is enabled, and holds the control clock to a specific level and provides the held control clock to the second output selecting flip-flop when the output control signal is disabled.

14. The address delay circuit according to claim 12, wherein the first output selecting flip-flop delays the delayed address and outputs the delayed address through the first output terminal when the output control signal is enabled, and delays the delayed address and output the delayed address as the internal address through the second output terminal when the output control signal is disabled.
